(19) United States
(12) Patent Application Publication
(10) Pub. No.: US 2025/0149327 A1
(43) Pub. Date: May 8, 2025

(54) SUBSTRATE PROCESSING METHOD AND SUBSTRATE PROCESSING SYSTEM

(71) Applicant: SCREEN HOLDINGS CO., LTD., Kyoto (JP)

(72) Inventors: Noritake SUMI, Kyoto (JP); Takaaki ISHIZU, Kyoto (JP); Tomoaki MAEDA, Kyoto (JP)

(21) Appl. No.: 18/839,021

(22) PCT Filed: Feb. 14, 2023
(86) PCT No.: PCT/JP2023/004898

§ 371 Date: Aug. 15, 2024

(30) Foreign Application Priority Data
Feb. 28, 2022 (JP) 2022-028917

(51) Int. Cl. H01L 21/02; B08B 3/08; B08B 3/10; F26B 5/00; H01L 21/67

(52) U.S. Cl. CPC H01L 21/02101; B08B 3/08; B08B 3/10; F26B 5/005; H01L 21/67034

(57) ABSTRACT

In a substrate processing method and a substrate processing system according to the present invention, a liquid film is formed of a liquid containing ultrafine bubbles on a surface of a substrate held in a substantially horizontal position, a processing fluid not in a supercritical state is introduced into a chamber in which the substrate with the liquid film formed thereon is accommodated, the processing fluid is pressurized to be brought into a supercritical state, the liquid on the surface of the substrate is replaced with the processing fluid, the chamber is decompressed, and the processing fluid in the supercritical state is vaporized to be discharged to the outside of the chamber. In a technique for processing a substrate with a processing fluid in a supercritical state inside a chamber, it is capable of satisfactorily replacing the liquid with the processing fluid before coming into the supercritical state.

### TECHNICAL FIELD

This invention relates to a technique for processing a substrate with a processing fluid in a supercritical state inside a chamber, and more particularly to a technique for processing a substrate covered with a liquid film with a supercritical processing fluid.

### BACKGROUND

Processing steps of various substrates such as semiconductor substrates and glass substrates for display device include processing of a substrate surface by various processing fluids. A wet processing using a liquid such as a chemical or a rinse liquid as a processing fluid has been conventionally widely performed. In recent years, a processing using a supercritical processing fluid has also been put to practical use. Particularly, a supercritical processing fluid has a property of having a lower surface tension than liquids and entering deep into gaps of the pattern. Therefore, the processing can be efficiently performed, and it is also possible to reduce an occurrence risk of pattern collapse due to a surface tension during drying.

Patent Literature 1, for example, discloses a substrate processing apparatus for replacing a liquid adhered to a substrate with a supercritical fluid and performing a drying process of the substrate. More specifically, in Patent Literature 1, an operation flow of the drying process in a case where carbon dioxide is used as a supercritical processing fluid and IPA (isopropyl alcohol) is used as a replacement target liquid to be replaced therewith is described in detail. In this technique, the substrate puddled with IPA for preventing dryness on a surface thereof is accommodated in a chamber and subsequently the chamber is filled with the processing fluid and the pressure therein is boosted. After a state where the pressure and the temperature in the chamber exceed the critical pressure and the critical temperature of the processing fluid, respectively, is maintained for a predetermined period, the chamber is decompressed, and a series of processing is thus ended. Further, in Patent Literature 2, disclosed is pressure control during decompression in a similar supercritical drying process.

### CITATION LIST

### Patent Literature

Patent Literature 1: JP2020-191479A
Patent Literature 2: JP2018-152479A

### SUMMARY

### Technical Problem

In order to increase the efficiency of the supercritical drying process, it is necessary to shorten the processing time in the individual processes, i.e., each of the processes of pressure boosting, maintaining the supercritical state, and decompression. Though progress management in the supercritical state and the decompression process is considered in details in Patent Literatures 1 and 2, the pressure boosting process from the time when the processing fluid is introduced to the time when the processing fluid is brought into the supercritical state is not described in detail.

In order to satisfactorily and efficiently progress the pressure boosting process, it is necessary to efficiently replace the liquid adhered to the substrate with the processing fluid. No means for this, however, is described in Patent Literature 1 or 2. Further, when the pressure boosting speed is just simply increased to shorten the processing time, replacement of the liquid does not sufficiently proceed and the liquid remains on the substrate, and this may affect the later processing.

### Solution to Problem

This invention is intended to solve the above-described problem, and an object of this invention is, in the technique for processing a substrate with the processing fluid in the supercritical state inside a chamber, to provide a technique for satisfactorily replacing a liquid with a processing fluid before coming into a supercritical state.

One aspect of this invention is intended for a substrate processing method for processing a substrate with a processing fluid in a supercritical state inside a chamber, and the substrate processing method includes a step of forming a liquid film by using a liquid containing ultrafine bubbles on a surface of the substrate held in a horizontal posture, a step of introducing the processing fluid not in the supercritical state into the chamber in which the substrate with the liquid film formed thereon is accommodated, pressurizing the processing fluid to be brought into the supercritical state, and replacing the liquid on the surface of the substrate with the processing fluid, and a step of decompressing the chamber and vaporizing the processing fluid in the supercritical state and thereby discharging the processing fluid to the outside of the chamber.

Herein, ultrafine bubbles (hereinafter, sometimes abbreviated to “UFBs”) in the present invention refer to bubbles each having a diameter of 1 μm or less, and more preferably a diameter of 0.1 μm or less. The diameter of the bubble can be represented by the median or the maximum value in the diameter distribution. The gas forming the bubble has the same composition as the component contained in the liquid forming the liquid film or is gas having another composition, which is introduced from the outside.

The liquid to which the UFBs are added has the following effect. First, since the impact generated when the fine bubbles are collapsed reduces the intermolecular forces of the liquid, the surface tension of the liquid decreases. The fluidity of the liquid thereby increases, and, for example, the thermal conductivity of the liquid increases. Further, since the diameter is small, the bubbles enter a small clearance and have an action of removing substances adhered to each other, from each other. Thus, addition of the UFBs produces an effect of improving the property of the liquid.

These actions can be useful also in substrate processing. Specifically, a cleaning action of the substrate with the liquid can be increased, and particularly in the substrate having a surface on which a fine pattern is formed, the effect becomes significant. However, the property improvement effect of the liquid by addition of the UFBs as described above is relatively gentle. For this reason, a high effect cannot be necessarily exhibited in the process in a short time.

In the present invention, the surface of the substrate accommodated in the chamber where the supercritical processing is performed is covered with a liquid film of the liquid containing the UFBs. Then, the processing fluid in a non-supercritical state is introduced into the chamber and pressurized, and is brought into the supercritical state in the end. At that time, high pressure to bring the processing fluid into the supercritical state is also applied to the liquid and the UFBs contained therein, and the UFBs further contract in the liquid and lead to collapse in a short time. In other words, since the UFBs are crushed in the liquid by pressurization, effects of reducing the surface tension of the liquid, improving the cleaning action, increasing the thermal conductivity, and the like can be produced even in a short time.

For this reason, in the pressurizing process until the processing fluid comes into the supercritical state, the liquid having increased fluidity is easily withdrawn from the surface of the substrate and replacement of the liquid with the processing fluid is promoted. Further, at that time, impurities or the like which are residually adhered to the surface of the substrate or mixed into the processing fluid can be removed. Furthermore, since the bubbles are contracted by the pressurization and intrude into the deep portion of the pattern, the above-described effects become effective even in the substrate on which the fine pattern is formed.

As described above, according to the present invention, since the liquid film covering the substrate is formed of the liquid containing the UFBs and is pressurized, it becomes possible to produce the property improvement effect of the liquid with the UFBs in a short time. For this reason, the liquid containing the UFBs can be suitably applied to the substrate processing. In the supercritical processing, the efficiency in replacing the liquid adhered to the substrate with the processing fluid can be increased and the effect of removing the impurities by the liquid can be also increased, and further the time required for the pressurizing process can be shortened.

Further, another aspect of this invention is intended for a substrate processing system for processing a substrate with a processing fluid in a supercritical state, and the substrate processing system includes a liquid film forming part for forming a liquid film by using a liquid containing ultrafine bubbles on a surface of the substrate held in a substantially horizontal posture, a chamber for accommodating therein the substrate on which the liquid film is formed, and a fluid supplier for supplying the processing fluid not in the supercritical state into the chamber and pressurizing the processing fluid to be brought into the supercritical state.

In the invention thus configured, the liquid film of the liquid containing the UFBs is formed on the substrate conveyed into the chamber where the processing using the supercritical processing fluid is performed thereon. For this reason, the property of the liquid is improved by pressurizing the UFBs in the liquid on the above-described principle, and replacement of the liquid with the processing fluid and the later supercritical processing can be satisfactorily performed.

### Advantageous Effects of Invention

Thus, in the present invention, the substrate having the surface covered with the liquid containing the UFBs is accommodated into the chamber, and the processing fluid is introduced into the chamber and pressurized to be brought into the supercritical state. For this reason, the property improvement effect of the liquid with the UFBs can be produced in a short time, and replacement of the liquid with the processing fluid and the later supercritical processing can be satisfactorily performed.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF DRAWINGS

FIG. 1 is a view showing a schematic configuration of one embodiment of a substrate processing system in accordance with the present invention;

FIG. 2A is a view showing an exemplary configuration of a wet processing apparatus;

FIG. 2B is a view showing an exemplary configuration of the wet processing apparatus:

FIG. 3 is a side elevational view showing a configuration of a supercritical processing apparatus;

FIG. 4 is a flowchart showing an overview of a process performed by this substrate processing system;

FIG. 5 is a view showing pressure change inside a processing chamber;

FIG. 6A is a view schematically showing an action of UFBs in a liquid; and

FIG. 6B is a view schematically showing an action of the UFBs in the liquid.

### DESCRIPTION OF EMBODIMENTS

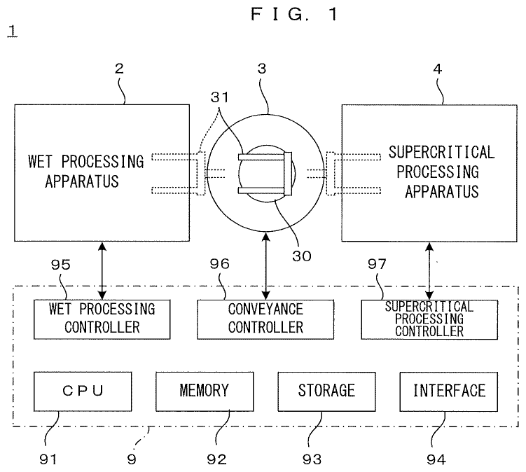

FIG. 1 is a view showing a schematic configuration of one embodiment of a substrate processing system in accordance with the present invention. This substrate processing system 1 is a processing system for wet-processing various substrates such as semiconductor wafers by supplying a processing fluid to an upper surfaces of the substrates and, thereafter, drying the substrates. The substrate processing system 1 has a suitable system configuration to carry out a substrate processing method according to the invention. That is, the substrate processing system 1 includes a wet processing apparatus 2, a conveyance mechanism 3, a supercritical processing apparatus 4 and a control part 9.

The wet processing apparatus 2 performs a predetermined wet processing by receiving a substrate to be processed. Contents of the processing are not particularly limited. The conveyance mechanism 3 carries out and conveys the substrate after the wet processing from the substrate processing apparatus 2, and carries the substrate into the supercritical processing apparatus 4. The supercritical processing apparatus 4 performs a dry processing (supercritical dry processing) using a processing fluid in a supercritical state for the carried-in substrate. These are installed in a clean room. Therefore, the conveyance mechanism 3 conveys the substrate in an air atmosphere and under an atmospheric pressure.

The control part 9 realizes a predetermined process by controlling the operations of these apparatuses. For this purpose, the control part 9 includes a CPU 91, a memory 92, a storage 93, an interface 94, and the like. The CPU 91 executes various control programs. The memory 92 temporarily stores processing data. The storage 93 stores the control programs to be executed by the CPU 91. The interface 94 performs information exchange with a user and an external apparatus. Operations of the apparatus to be described later are realized by the CPU 91 causing each component of the apparatus to perform a predetermined operation by executing the control program written in the storage 93 in advance.

The CPU 91 executes a predetermined control program, whereby functional blocks such as a wet processing controller 95 for controlling the operation of the wet processing apparatus 2, a conveyance controller 96 for controlling the operation of the conveyance mechanism 3 and a supercritical processing controller 97 for controlling the operation of the supercritical processing apparatus 4 are realized by software in the control part 9. Note that each of these functional blocks may be at least partially configured by dedicated hardware.

Here, various substrates such as semiconductor wafers, glass substrates for photomask, glass substrates for liquid crystal display, glass substrates for plasma display, substrates for FED (Field Emission Display), optical disk substrates, magnetic disk substrates and magneto-optical disk substrates can be applied as the “substrate” in this embodiment. The substrate processing apparatus used in processing disk-shaped semiconductor wafers is mainly described as an example with reference to the drawings below. However, application to the processing of various substrates illustrated above is also possible. Further, various shapes of the substrate are also available.

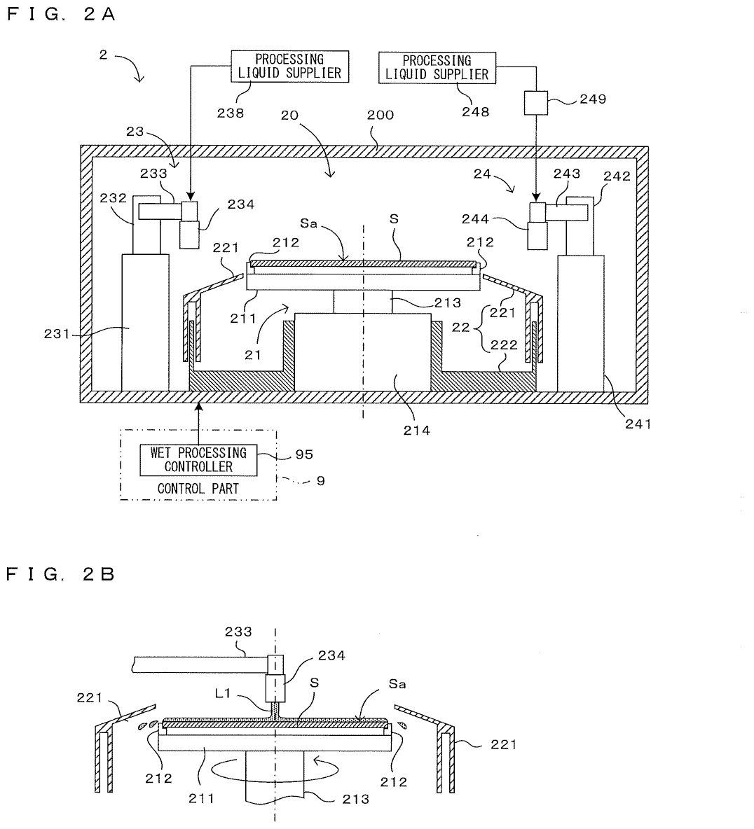

FIGS. 2A and 2B are views each showing an exemplary configuration of the wet processing apparatus. More specifically, FIG. 2A is a side elevational view showing an overall configuration of the wet processing apparatus 2. Further, FIG. 2B is a view showing an operation of the wet processing apparatus 2. This wet processing apparatus 2 is an apparatus for processing the substrate by supplying the processing fluid to the upper surface of the substrate. The operation of the wet processing apparatus 2 is controlled by the wet processing controller 95 of the control part 9.

The wet processing apparatus 2 supplies a processing liquid to an upper surface of a substrate S and performs a wet processing such as a surface processing for the substrate S cleaning processing, or the like. For this purpose, the wet processing apparatus 2 is provided with a substrate holder 21, a splash guard 22 and processing liquid suppliers 23, 24 inside the processing chamber 200. The operations of these are controlled by the wet processing controller 95 provided in the control part 9. The substrate holder 21 includes a disk-like spin chuck 211 having a diameter nearly equal to that of the substrate S, and a plurality of chuck pins 212 are provided on a peripheral edge part of the substrate S. The chuck pins 211 support the substrate S by contacting a peripheral part of the substrate S, thereby the spin chuck 211 can support the substrate S in the horizontal posture in a state that the substrate S is apart from an upper surface thereof.

The spin chuck 211 is so supported that the upper surface thereof is horizontal by a rotary support shaft 213 extending downward from a central part of the lower surface of the spin chuck 211. The rotary support shaft 213 is rotatably supported by a rotating mechanism 214 mounted in a bottom part of the processing chamber 200. The rotating mechanism 214 includes an unillustrated built-in rotary motor. The rotary motor rotates in response to a control command from the control part 9, whereby the spin chuck 211 directly coupled to the rotary support shaft 213 rotates about the axis of rotation indicated by a dashed-dotted line. In FIG. 2A and FIG. 2B, an up-down direction is a vertical direction. In this way, the substrate S is rotated about the axis of rotation while being held in a horizontal position.

The splash guard 22 is provided to laterally surround the substrate holder 21. The splash guard 22 includes a substantially tubular cup 221 provided to cover the peripheral edge part of the spin chuck 211 and a liquid receiver 222 provided below an outer peripheral part of the cup 221. The cup 211 is raised and lowered in response to a control command from the control part 9. The cup 221 is raised and lowered between a lower position shown in FIG. 2A and an upper position shown in FIG. 2B. At the lower position, an upper end part of the cup 221 is lowered to below the peripheral edge part of the substrate S held by the spin chuck 211. At the upper position, the upper end part of the cup 221 is located above the peripheral edge part of the substrate S.

As shown in FIG. 2A, when the cup 221 is at the lower position, the substrate S held by the spin chuck 211 is exposed to the outside of the cup 221. Thus, the cup 221 is prevented from becoming an obstacle when, for example, the substrate S is carried to and from the spin chuck 211.

Further, as shown in FIG. 2B, the cup 221 surrounds the peripheral edge part of the substrate S held by the spin chuck 211 when being at the upper position. In this way, the processing liquid shaken off from the peripheral edge part of the substrate S during liquid supply to be described later is prevented from scattering in the chamber 200, and the processing liquid can be reliably collected. That is, by the rotation of the substrate S, droplets of the processing liquid shaken off from the peripheral edge part of the substrate S adhere to the inner wall of the cup 221, flow down and are finally gathered and collected by the liquid receiver 222 arranged below the cup 221. To individually collect a plurality of processing liquids, cups may be concentrically provided at a plurality of levels.

The processing liquid supplier 23 is structured such that a nozzle 234 is attached to the tip of an arm 233 horizontally extending from a rotary support shaft 232 provided rotatably with respect to a base 231 fixed in the processing chamber 200. The rotary support shaft 232 rotates in response to a control command from the control part 9, whereby the arm 233 pivots. In this way, the nozzle 234 on the tip of the arm 233 moves between a retreated position shown in FIG. 2A retreated laterally from above the substrate S and a processing position shown in FIG. 2B above the substrate S.

The nozzle 234 is connected to a processing liquid supply source 238. If an appropriate processing liquid is sent out from the processing liquid supply source 238, the processing liquid is discharged toward the substrate S from the nozzle 234. As shown in FIG. 2B, by supplying the processing liquid LI from the nozzle 234 positioned above a center of rotation of the substrate S while rotating the substrate S by the rotation of the spin chuck 211 at a relatively low speed, an upper surface Sa of the substrate S is processed by the processing liquid LI. Liquids having various functions such as developing liquids, etching liquids, cleaning liquids, rinsing liquids and the like can be used as the processing liquid LI, and a composition of the processing liquid is arbitrary. Further, the processing may be performed with a plurality of types of processing liquids combined.

Another processing liquid supplier 24 also has a configuration corresponding to the first processing liquid supplier 23 described above. That is, the second processing liquid supplier 24 includes a base 241, a rotary support shaft 242, an arm 243, a nozzle 244 and the like. The configurations of these are the same as those of the corresponding components of the first processing liquid supplier 23. The rotary support shaft 242 rotates in response to a control command from the control part 9, whereby the arm 243 pivots. The nozzle 244 on the tip of the arm 243 supplies a processing liquid to the upper surface Sa of the substrate S.

In this embodiment, the second processing liquid supplier 24 is used for the purpose of forming a liquid film for preventing dryness on the substrate S after the wet processing. That is, the substrate S after the wet processing is conveyed to the supercritical processing apparatus 4 and receives a supercritical drying processing. To prevent the surface of the substrate S from being exposed and oxidized during conveyance and prevent the collapse of the fine pattern formed on the surface, the substrate S is conveyed with the surface thereof covered with a puddle-like liquid film.

A substance having a lower surface tension than water, which is a main component of a processing liquid used in a cleaning processing, e.g. an organic solvent such as isopropyl alcohol (IPA) or acetone, is used as the liquid for constituting the liquid film.

In various cleaning processing using a liquid, in order to increase a cleaning effect, a technique has been used, for containing bubbles each having a micro diameter, referred to as ultrafine bubbles (UFBs) or nano bubbles, into a liquid. In JP2015-066470, for example, disclosed is a technique for cleaning a silicon wafer in a flowing cleaning solution in which UFBs each having a diameter of 1 μm or less are mixed into ultrapure water.

On the other hand, in this embodiment, a liquid film is formed by using IPA containing the UFBs. For this purpose, the second processing liquid supplier 24 includes a processing liquid supply source 248 for supplying IPA and a UFB generator 249 interposed in a pipe extending from the processing liquid supply source 248 to the nozzle 244. For example, a UFB generator for generating UFBs each having a diameter of 1 μm or less and mixing the UFBs into a liquid has been put into practical use, and also in this embodiment, such a device can be used. The gas forming the bubble has the same component as that of the liquid. Further, the UFB generator 249 may be a device for introducing an inert gas (e.g., nitrogen gas) from the outside and mixing bubbles of the gas into the liquid.

Although two processing liquid suppliers are provided in the wet processing apparatus 2 here, the number, structures and functions of the processing liquid suppliers are not limited to these. For example, only one processing liquid supplier may be provided or three or more processing liquid suppliers may be provided. Further, one processing liquid supplier may include a plurality of nozzles. For example, a plurality of nozzles may be provided on the tip of one arm. Further, the processing liquid is not only discharged with the nozzle positioned at the predetermined position as described above, but also may be, for example, discharged while the nozzle is scanned and moved along the upper surface Sa of the substrate S. Further, a gas supplier with a nozzle discharging gas may be further disposed. Furthermore, at least one of multiple nozzles disposed in the liquid supplier may be configured to discharge gas.

Referring back to FIG. 1, the conveyance mechanism 3 is provided with a conveyor robot 30 provided with a hand 31 on the tip of a telescopic/rotatable arm. The hand 31 can support the substrate by partially contacting the lower surface of the substrate and, as shown by dotted lines in FIG. 1, is movable toward and away from both the wet processing apparatus 2 and the supercritical processing apparatus 4. In this way, the substrate can be carried in and out from each of the wet processing apparatus 2 and the supercritical processing apparatus 4. The operation of the conveyor robot 30 is controlled by the conveyance controller 96 of the control part 9. Many techniques are known as conveyor robots of this type, and one of those can be appropriately selected and used also in this embodiment. Therefore, detailed description is omitted.

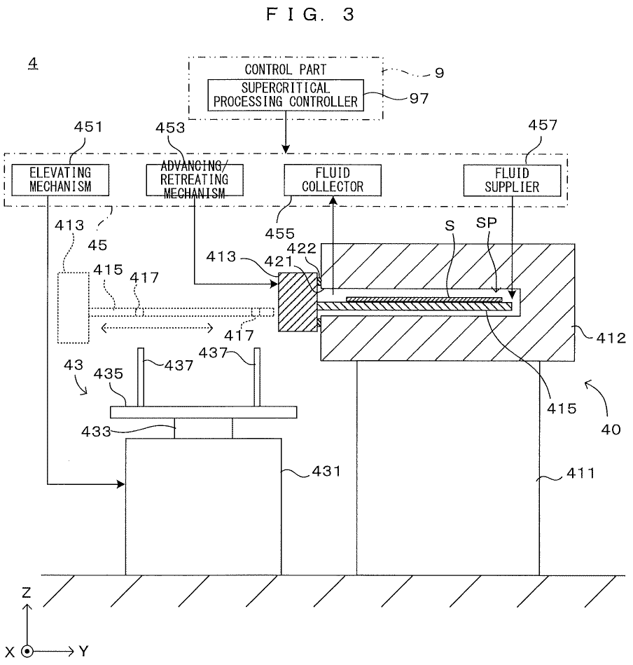

FIG. 3 is a side elevational view showing a configuration of the supercritical processing apparatus. The supercritical processing apparatus 4 is an apparatus for applying a drying processing using a processing fluid in a supercritical state to the substrate S after the wet processing. More specifically, the supercritical processing apparatus 4 finally brings the substrate S to a dry state by discharging the processing fluid after receiving the substrate S after the wet processing and replacing the liquid remaining on the substrate S by the processing fluid in the supercritical state.

The supercritical processing apparatus 4 is provided with a processing unit 40, a transfer unit 43 and a supply unit 45. The processing unit 40 serves as an executor of the supercritical drying processing. The transfer unit 43 receives the substrate S after the wet processing conveyed by the conveyance mechanism 3, carries the substrate S into the processing unit 40 and transfers the processed substrate S from the processing unit 40 to an external conveyor device. The supply unit 45 supplies chemical substances, power, energy and the like necessary for the processing to the processing unit 40 and the transfer unit 43. These operations are controlled by the control part 9, particularly by the supercritical processing controller 97.

The processing unit 40 is structured such that a processing chamber 412 is mounted on a pedestal 411. The processing chamber 412 is configured by a combination of several metal blocks and the inside thereof is hollow and constitutes a processing space SP. The substrate S to be processed is carried into the processing space SP and processed. A slit-like opening 421 elongated in the X direction is formed in a side surface on the (−Y) side of the processing chamber 412. The processing space SP and an outside space communicate via the opening 421. A cross-sectional shape of the processing space SP is substantially the same as an opening shape of the opening 421. That is, the processing space SP is a hollow having a cross-sectional shape long in the X direction and short in the Z direction and extending in the Y direction.

A lid member 413 is provided to close the opening 421 on a side surface on the (−Y) side of the processing chamber 412. The lid member 413 closes the opening 421 of the processing chamber 412, whereby an airtight processing container is configured. In this way, the substrate S can be processed under a high pressure in the processing space SP inside. A support tray 415 in the form of a flat plate is mounted in a horizontal position on a side surface on the (+Y) side of the lid member 413. The upper surface of the support tray 415 serves as a support surface, on which the substrate S can be placed. The lid member 413 is supported horizontally movably in the Y direction by an unillustrated supporting mechanism.

The lid member 413 is movable toward and away from the processing chamber 412 by an advancing/retreating mechanism 453 provided in the supply unit 45. Specifically, the advancing/retreating mechanism 453 includes a linear motion mechanism such as a linear motor, a linear motion guide, a ball screw mechanism, a solenoid or an air cylinder. Such a linear motion mechanism moves the lid member 413 in the Y direction. The advancing/retreating mechanism 453 operates in response to a control command from the control part 9.

The lid member 413 is separated from the processing chamber 412 by moving in the (−Y) direction. If the support tray 415 is pulled out from the processing space SP to outside via the opening 421 as indicated by a dotted line, the support tray 415 becomes accessible. That is, the substrate S can be placed on the support tray 415 and the substrate S placed on the support tray 415 can be taken out. On the other hand, by a movement of the lid member 413 in the (+Y) direction, the support tray 415 is accommodated into the processing space SP. If the substrate S is placed on the support tray 415, the substrate S is carried into the processing space SP together with the support tray 415.

The processing space SP is closed by the lid member 413 moving in the (+Y) direction and closing the opening 421. A sealing member 422 is provided between the side surface on the (+Y) side of the lid member 413 and the side surface on the (−Y) side of the processing chamber 412 to hold the processing space SP airtight. The sealing member 422 is, for example, made of rubber. Further, the lid member 413 is fixed to the processing chamber 412 by an unillustrated lock mechanism. As just described, in this embodiment, the lid member 413 is switched between a closing state (solid line) for sealing the processing space SP by closing the opening 421 and a separated state (dotted line) where the lid member 413 is largely separated from the opening 421 to enable the substrate S to be taken in and out.

With the airtight state of the processing space SP ensured, the substrate S is processed in the processing space SP. In this embodiment, a fluid supplier 457 provided in the supply unit 45 sends out a processing fluid and further brings the processing fluid into a supercritical state by pressurizing the processing fluid in the processing chamber 412. The processing fluid is supplied in a gas or liquid state to the processing unit 40. A substance usable in the supercritical processing, e.g. carbon dioxide, can be used as the processing fluid. Carbon dioxide is a chemical substance suitable for the supercritical drying processing in having a property of entering the supercritical state at relatively low temperature and low pressure and dissolving into an organic solvent often used in substrate processing well. At a critical point at which carbon dioxide enters the supercritical state, an atmospheric pressure (critical pressure) is 7.38 MPa and a temperature (critical temperature) is 31.1° C.

If the processing fluid is filled into the processing space SP and the inside of the processing space SP reaches suitable temperature and pressure, the processing space SP is filled with the processing fluid in the supercritical state. In this way, the substrate S is processed by the processing fluid in the supercritical state in the processing chamber 412. The supply unit 45 is provided with a fluid collector 455, and the fluid after the processing is collected by the fluid collector 455. The fluid supplier 457 and the fluid collector 455 are controlled by the supercritical processing controller 97.

The processing space SP has a shape and a volume capable of receiving the support tray 415 and the substrate S supported by the support tray 415. That is, the processing space SP has a substantially rectangular cross-sectional shape wider than a width of the support tray 415 in a horizontal direction and having a height larger than that of the support tray 415 and substrate S combined in the vertical direction. Further, the processing space SP has a depth capable of receiving the support tray 415. As just described, the processing space SP has a shape and a volume enough to receive the support tray 415 and the substrate S. However, gaps between the support tray 415 and the substrate S and the inner wall surface of the processing space SP are tiny. Therefore, the amount of the processing fluid necessary to fill the processing space SP can be relatively small.

The fluid supplier 457 supplies the processing fluid to the processing space SP on a side further in the (+Y) direction than the end part on the (+Y) side of the substrate S. On the other hand, the fluid collector 55 discharges the processing fluid flowing in a space above the substrate S and a space below the support tray 415, out of the processing space SP, on a side further in the (−Y) direction than the end part on the (−Y) side of the substrate S. In this way, laminar flows of the processing fluid from the (+Y) side toward the (−Y) side are respectively formed above the substrate S and below the support tray 415 in the processing space SP.

The supercritical processing controller 97 of the control part 9 specifies the pressure and temperature in the processing space SP based on a detection result of an unillustrated detector and controls the fluid supplier 457 and the fluid collector 455 based on that result. In this way, the supply of the processing fluid into the processing space SP and the discharge of the processing fluid from the processing space SP are properly managed and the pressure and temperature in the processing space SP are adjusted according to a processing recipe determined in advance.

The transfer unit 43 is in charge of the transfer of the substrate S between the conveyance mechanism 3 and the support tray 415. For this purpose, the transfer unit 43 is provided with a body 431, an elevating member 433, a base member 435 and a plurality of lift pins 437. The elevating member 433 is a columnar member extending in the Z direction, and supported movably in the Z direction with respect to the body 431 by an unillustrated supporting mechanism. The base member 435 having a substantially horizontal upper surface is mounted atop the elevating member 433. The plurality of lift pins 437 stand up from the upper surface of the base member 435. The respective lift pins 437 support the substrate S in a horizontal position from below by the contact of upper end parts thereof with the lower surface of the substrate S. Three or more lift pins 437 having the upper end parts at the same height are desirably provided to stably support the substrate S in the horizontal position.

The elevating member 433 is made movable up and down by an elevating mechanism 451 provided in the supply unit 45. Specifically, the elevating mechanism 451 includes a linear motion mechanism such as a linear motor, a linear motion guide, a ball screw mechanism, a solenoid or an air cylinder, and such a linear motion mechanism moves the elevating member 433 in the Z direction. The elevating mechanism 451 operates in response to a control command from the control part 9.

The base member 435 is moved up and down by upward and downward movements of the elevating member 433, and the plurality of lift pins 437 move up and down integrally with the base member 435. In this way, the transfer of the substrate S is realized between the transfer unit 43 and the support tray 415. More specifically, as shown by dotted lines in FIG. 3, the substrate S is transferred with the support tray 415 pulled out to the outside of the chamber. For this purpose, the support tray 415 is provided with through holes 419, through which the lift pins 437 are inserted. If the base member 435 is raised, the upper ends of the lift pins 437 reach above the upper surface of the support tray 415 through the through holes 419. In this state, the substrate S conveyed by the conveyor robot 30 is transferred from the hand 31 of the conveyor robot 30 to the lift pins 437. By lowering the lift pins 437, the substrate S is transferred from the lift pins 437 to the support tray 415. The substrate S can be carried out by a procedure opposite to the above one.

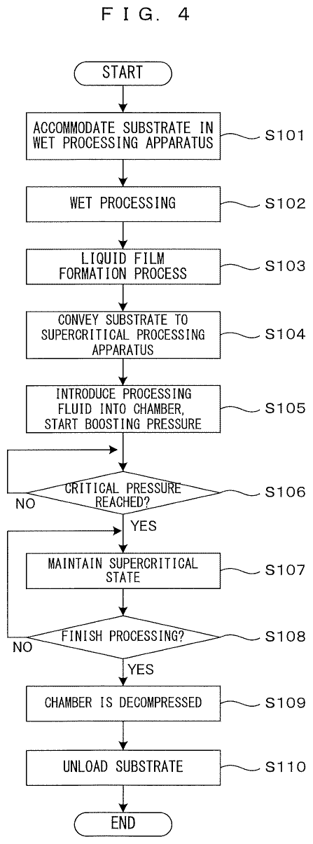

FIG. 4 is a flowchart showing an overview of a process performed by this substrate processing system. This substrate processing system 1 receives a substrate S to be processed and successively performs the wet processing using processing liquids and the supercritical dry processing using a supercritical processing fluid. Details are as follows. The substrate S to be processed is accommodated to the wet processing apparatus 2 making up the substrate processing system 1 (Step S101). The substrate S may be directly carried in by an external conveying device or may be carried in from the external conveying device via the conveyor robot 30.

The wet processing apparatus 2 performs the wet processing on the substrate S by using a predetermined processing liquid (Step S102). After that, a liquid film formation process for forming a liquid film by using an organic solvent such as IPA or the like is performed (Step S103). The IPA used for forming the liquid film is supplied onto the substrate S through the UFB generator 249 from the processing liquid supply source 248 and contains the UFBs.

For example, if a fine pattern is formed in the surface of the substrate S, there is a possibility that the pattern collapses due to a surface tension of the liquid residually adhering the substrate S. Further, water marks may remain on the surface Sa of the substrate S due to incomplete drying. Furthermore, the surface of the substrate S may undergo deterioration such as oxidation by being exposed to outside air. To avoid such a problem, the substrate S may be carried in a state that the surface (pattern formed surface) of the substrate S is covered with a solid or liquid surface layer.

For example, if a cleaning liquid mainly contains water, the substrate is conveyed in a state where a liquid film is formed by a liquid having a lower surface tension than water and having low corrosiveness to the substrate, e.g. an organic solvent such as IPA or acetone. That is, the substrate S is conveyed from the wet processing apparatus 2 to the supercritical processing apparatus 4 by the conveyor device 3 while being horizontally supported and having a liquid film formed on the upper surface thereof, further conveyed (Step S104).

The substrate S conveyed to the supercritical processing apparatus 4 is accommodated into the processing chamber 412. Specifically, the substrate S is conveyed with the pattern formed surface faced up and covered with the thin liquid film. As shown by dotted lines in FIG. 3, the lift pins 437 are lifted with the lid member 413 moved to the (−Y) side and the support tray 415 pulled out. The conveying device transfers the substrate S to the lift pins 437. By lowering the lift pins 437, the substrate S is placed on the support tray 415. If the support tray 415 and the lid member 413 integrally move in the (+Y) direction, the support tray 415 supporting the substrate S is accommodated into the processing space SP in the processing chamber 412 and the opening 421 is closed by the lid member 413.

In this state, carbon dioxide serving as the processing fluid is introduced in a gas phase state into the processing space SP (Step S105). Although outside air enters the processing space SP when the substrate S is carried in, the outside air can be replaced by introducing the processing fluid in a gas phase. By injecting the processing fluid in the gas phase, a pressure in the processing chamber 412 is increased.

Note that the processing fluid is continuously discharged from the processing space SP in the process of introducing the processing fluid. That is, the processing fluid is discharged from the processing space SP by the fluid collector 455 also while the processing fluid is introduced by the fluid supplier 457. In this way, the processing fluid used for the processing is discharged into the processing space SP without staying. Therefore, impurities such as residues taken into the processing fluid are prevented from re-adhering to the substrate S.

If a supply amount of the processing fluid is more than a discharge amount, a density of the processing fluid in the processing space SP increases and a chamber inner pressure increases. Conversely, if the supply amount of the processing fluid is less than the discharge amount, the density of the processing fluid in the processing space SP decreases and the chamber inner pressure decreases. The processing fluid is supplied into the processing chamber 412 and discharged from the processing chamber 12 based on a supply/discharge recipe prepared in advance. That is, the control part 9 adjusts supply/discharge timings, a flow rate and the like of the processing fluid by controlling the fluid supplier 457 and the fluid collector 455 based on the supply/discharge recipe.

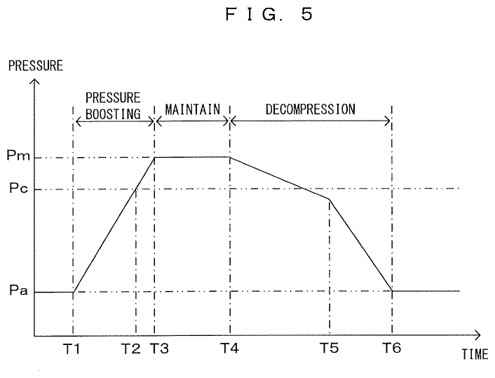

FIG. 5 is a view showing pressure change inside the processing chamber. If the processing fluid is carbon dioxide, a temperature change during the processing is not very large since a critical temperature of the processing fluid is not very different from a room temperature. Here, a phenomenon is described, focusing on the chamber inner pressure, which notably changes. The introduction of the processing fluid is started at time T1 and the internal pressure starts to increase after the processing space SP is closed from a state where the processing space SP is open to atmospheric air and the internal pressure is an atmospheric pressure Pa.

Pressurization is continued until the pressure of the processing fluid increases in the processing space SP and exceeds a critical pressure Pc in the processing space SP (Step S106). At time T2 at which the critical pressure Pc is reached in the chamber, the processing fluid enters the supercritical state in the chamber. That is, the processing fluid transitions from the gas phase to the supercritical state due to a phase change in the processing space SP. By filling the processing space SP with the processing fluid in the state, the organic solvent such as IPA covering the substrate is replaced by the supercritical processing fluid. The organic solvent liberated from the surface of the substrate S is discharged from the processing chamber 412 together with the processing fluid while being dissolved in the processing fluid, and removed from the substrate S. That is, the processing fluid in the supercritical state has a function of replacing the organic solvent adhering to the substrate S as a liquid to be replaced, and discharging the liquid to be replaced to the outside of the processing chamber 412.

By continuing a state where the processing space SP is filled with the processing fluid in the supercritical state for a predetermined time after time T3 at which the processing fluid has reliably transitioned into the supercritical state (Steps S107, S108), the liquid to be replaced adhering to the substrate S can be completely replaced and discharged to the outside of the chamber. Note that although a chamber inner pressure Pm in the supercritical state is shown to be constant in FIG. 5, the pressure may fluctuate within such a range as not to fall to or below the critical pressure Pc.

If the replacement of the liquid to be replaced by the processing fluid in the supercritical state is finished in the processing chamber 412 at time T4 (Step S108), the processing fluid in the processing space SP is discharged and the substrate S is dried. Specifically, the inside of the processing chamber 12 filled with the processing fluid in the supercritical state is decompressed by increasing the discharge amount of the fluid from the processing space SP (Step S109).

In a decompression process, the supply of the processing fluid may be stopped or a small amount of the processing fluid may be continuously supplied. By decompression from the state where the processing space SP is filled with the processing fluid in the supercritical state, the phase of the processing fluid changes from the supercritical state to the gas phase. By discharging the vaporized fluid to outside, the substrate S is dried. At this time, a decompression rate is so adjusted that a solid phase and a liquid phase are not created due to a sudden temperature drop. That is, decompression is performed at a relatively low decompression rate until time T5 at which the pressure reliably falls below the critical pressure Pc after decompression is started at time T4. In this way, the processing fluid in the processing space SP is directly vaporized from the supercritical state and discharged to outside.

At and after time T5 at which the processing fluid is completely vaporized, the decompression rate is increased, whereby decompression to the atmospheric pressure Pa is possible in a short time. By doing so, the processing fluid is not liquefied and the formation of a gas/liquid interface on the substrate S having the surface exposed after drying is avoided for an entire period from time T4 at which decompression is started to time T6 at which the pressure in the chamber falls to the atmospheric pressure Pa. Therefore, formation of the gas/liquid interface on the substrate of which the surface is exposed after drying is prevented.

As just described, in the supercritical dry processing of this embodiment, the liquid adhering to the substrate can be efficiently replaced and prevented from remaining on the substrate S by changing the phase of the processing fluid to the gas phase and discharging the processing fluid after the processing space SP is filled with the processing fluid in the supercritical state. Moreover, the substrate can be dried while avoiding problems caused by the formation of the gas/liquid interface such as the contamination of the substrate and pattern collapse due to the adhesion of impurities.

The processed substrate S is delivered to a post-process (Step S110). That is, the support tray 415 is pulled out from the processing chamber 412 by moving the lid member 413 in the (−Y) direction, and the substrate S is transferred to the external conveying device via the transfer unit 43. At this time, the substrate S is in a dry state. Contents of the post-process are arbitrary. In this way, the processing for one substrate S is completed. If there is a substrate to be processed next, return is made to Step S101, a new substrate S is received and the above processing is repeated.

In this embodiment, the substrate S after being subjected to the wet processing, which is loaded in the supercritical processing apparatus 4, has a surface with a liquid film of a liquid (IPA) containing the UFBs formed thereon. The reason why will be described next.

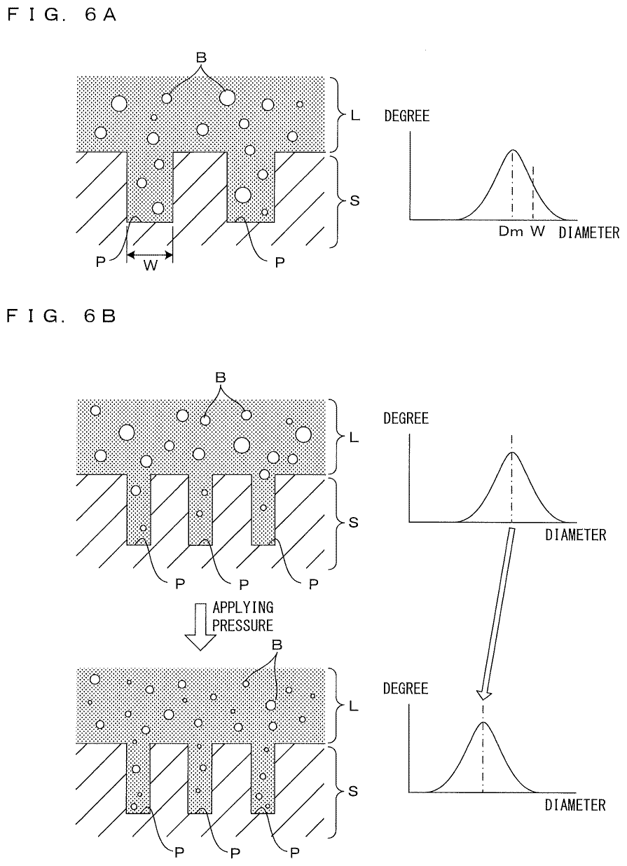

FIGS. 6A and 6B are views each schematically showing an action of the UFBs in the liquid. Considered is a state, as shown in FIG. 6A, where the surface of the substrate S, on which a trench-like pattern P is formed, is covered with a liquid L containing bubbles B which are UFBs. The typical width of the pattern P is represented by a reference sign W, and as a value representing the typical diameter Dm of the UFBs having various diameters, the median in a diameter distribution is used herein. Particularly, when paying attention to an effect inside the pattern P, however, an effective action is produced on the bubbles each having a diameter smaller than the pattern width W. From this, there is a possible case where the diameter Dm is represented by the substantial maximum value in the diameter distribution.

As shown in the graph on the right side of FIG. 6A, when the diameter Dm is smaller than the pattern width W, for example, many bubbles B each having a diameter smaller than the pattern width W are contained in the liquid L. The bubbles B produce the following action in the vicinity of the surface of the substrate S and inside the pattern P.

The UFBs which are very small bubbles are less affected by the buoyancy and therefore remain in the liquid for a long time. Then, since the impact (pressure wave) generated when the bubbles are collapsed reduces the intermolecular forces of the liquid, the surface tension of the liquid decreases and the fluidity thereof increases. Though a puddle-like liquid film is formed on the surface of the substrate S by the surface tension of the liquid L, the decrease in the surface tension reduces a force to maintain the liquid film. In other words, the excessive liquid which cannot be maintained drops off from the substrate S, to thereby make the liquid film thinner. While the liquid film has an action of protecting the surface of the substrate S during conveyance, the liquid film is a target to be replaced with the processing fluid in the supercritical processing. When the surface tension of the liquid L decreases, the amount of liquid L to be replaced on the substrate S is reduced and the efficiency of the replacement increases.

Further, the pressure wave in collapse of the bubbles B also reduces adhesion between the substrate S and impurities adhered onto the surface thereof and inside the pattern P. In other words, even when the impurities are residually adhered to the substrate S, the liquid L containing the UFBs has an action of removing the impurities. Furthermore, the liquid L has an action of preventing the impurities contained in the liquid L and the processing fluid from being adhered onto the substrate S. Thus, by adding the UFBs to the liquid L, it is possible to increase the effect of cleaning the substrate by the liquid L. Further, since the UFBs are contained in the liquid L, a frictional force between the liquid and a solid in contact therewith is reduced, and the thermal conductivity of the liquid increases. The thermal energy of the processing fluid is thereby efficiently transferred to the liquid, and this contributes to an increase in the replacement efficiency. Furthermore, since the liquid contains the bubbles, a cushioning action against the impact or the like increases, and it is thereby possible to suppress the pattern collapse.

Moreover, in a case where the bubble B is formed of a gas not containing oxygen, i.e., an inert gas such as nitrogen gas, an effect of suppressing oxidation of the surface of the substrate S increases while the liquid L in contact with the substrate S is brought into hypoxic conditions. It is thereby possible to produce, for example, an effect of suppressing the liquid film from adsorbing the moisture contained in the atmosphere until the substrate S is loaded in the supercritical processing apparatus 4 after the end of the wet processing.

A preferable value of the diameter Dm of the bubble B depends on the pattern width W. Specifically, as the diameter Dm becomes smaller, the amount of bubbles entering the inside of the pattern P increases and the action and effect thereof increases. Generally, the bubble having a diameter of 1 μm or less is referred to as UFB, and when the pattern width W is larger than 1 μm, the above-described effect can be produced by using the liquid containing such UFBs. When the pattern width W is smaller, particularly, it is preferable to use the UFB having a diameter of, e.g., about 0.1 μm.

The above-described effects each improve the property of the liquid L covering the substrate S, and this is advantageous in satisfactorily progressing the process while keeping the substrate S clean. The collapse phenomenon of the UFBs, however, proceeds relatively slowly. Further, at least inside the pattern P, only the bubbles B each having a diameter sufficiently smaller than the pattern width W can exhibit the effects. From these facts, generally, the effects are limited in the process in a short time. In the present embodiment, the liquid film containing the UFBs is formed on the surface of the substrate S under atmospheric pressure and the substrate S is conveyed into the processing chamber 412. During this process, the property improvement effect of the liquid by the UFBs is not very high.

On the other hand, inside the processing chamber 412 in which the substrate S is loaded, high pressure is also applied to the liquid film in the pressure boosting process of the processing fluid. For this reason, the bubbles B contained in the liquid L are also pressurized to contract, and as shown in FIG. 6B, the diameter distribution is shifted to a small diameter side. The bubbles B thereby easily enter also the inside of the fine pattern P and a small clearance between the substrate S and the impurities, and the action of the UFBs becomes more significant. Further, since the high pressure is sharply applied to each bubble B, the temperature of the gas inside the bubble B is raised by adiabatic expansion and the collapse (crushing) of the bubble B is promoted, and the above-described effects thereby become still more significant.

Thus, in this embodiment, the liquid film on the substrate S to which the high pressure is to be applied in the later supercritical processing is formed of the liquid L containing the UFBs. For this reason, various property improvement effects that the UFBs produce on the liquid become more significant under high pressure and are effectively exhibited even in a short time. It thereby becomes possible to satisfactorily progress the process while keeping the substrate S clean.

Specifically, in FIG. 5, during a period from the time T1 when the pressure boosting starts to the time T2 when the pressure inside the chamber reaches the critical pressure Pc, the bubbles B are sharply decompressed. The surface tension of the liquid L on the substrate S is thereby reduced and the liquid L becomes easier to be withdrawn from the substrate S. As a result, the replacement efficiency of the liquid L by the processing fluid increases. Further, at that time, increased is an effect of removing the impurities such as metals, organic substances, moisture, or the like which are residually adhered to the substrate S and contained in the liquid L and the processing fluid, from the substrate S. Since these impurities are discharged together with the liquid L, the substrate S can be kept clean.

Particularly, since the UFB is formed of a gas not containing oxygen, specifically e.g., nitrogen gas, it is possible to maintain the liquid L covering the substrate S in hypoxic conditions. It thereby becomes possible to avoid oxidation of the substrate S and suppress adsorption of moisture in the atmosphere.

Further, the property improvement effect on the liquid L from immediately after the start of pressure boosting is thus produced, and the replacement efficiency with the processing fluid increases. For this reason, it becomes possible to shorten the processing time required for the pressure boosting process (from the time T1 to the time T3 in FIG. 5). It is thereby possible to ensure reduction in a tact time in the supercritical processing.

As described above, in the substrate processing system 1 of the above-described embodiment, the wet processing apparatus 2 functions as a “liquid film forming part” of the present invention and the UFB generator 249 thereof functions as a “bubble generator” of the present invention. Further, the processing chamber and the fluid supplier 457 of the supercritical processing apparatus 4 function as a “chamber” and a “fluid supplier” of the present invention, respectively. Furthermore, the conveyance mechanism 3 functions as a “conveyor” of the present invention.

Note that the invention is not limited to the embodiments described above and various changes other than the aforementioned ones can be made without departing from the gist of the invention. For example, in the substrate processing system 1 of the above-described embodiment, the wet processing apparatus 2 is an apparatus for forming the liquid film formed of IPA after processing the substrate S with the processing liquid. As the “liquid film forming part” of the present invention, however, it is sufficient that the substrate S may be unloaded in the end, with the surface thereof covered with the liquid film containing the UFBs, and details of the processing as a preprocess thereof are not limited to the above and may be arbitrarily performed. Furthermore, the liquid film has only to cover the substrate S accommodated in the processing chamber 412, and the point in time when the liquid film is formed may be arbitrarily determined.

Further, various chemical substances used in the process of the above-described embodiment are only some examples, and various other chemical substances can be used instead of these if those chemical substances conform to the technical idea of the present invention described above.

As the specific embodiment has been illustrated above, in the substrate processing method in accordance with the present invention, the “ultrafine bubble” refers to bubble having a diameter of 1 μm or less, more preferably having a diameter of 0.1 μm or less. By using the liquid containing the bubbles each having such a diameter, it is possible to satisfactorily process even the substrate having a pattern size of micrometer order or less.

Further, for example, the substrate processing method in accordance with the present invention may further include a step of conveying the substrate on which the liquid film is formed outside the chamber, into chamber. Furthermore, the substrate processing system in accordance with the present invention may further include a conveyor for conveying the substrate on which the liquid film is formed by the liquid film forming part. In the conveyance under atmospheric pressure, which is achieved by these constituent elements, the action of the UFBs contained in the liquid becomes relatively gentle. Therefore, the surface tension of the liquid is relatively high and there is a low possibility that the liquid forming the liquid film may drop off from the substrate during the conveyance. The conveyance can be thereby easily achieved.

Further, in the substrate processing system in accordance with the present invention, the liquid film forming part may have a bubble generator for generating the UFBs in the liquid. With such a configuration, since the UFBs can be mixed into the liquid immediately before the liquid is supplied to the substrate, it is possible to form the liquid film formed of the liquid abundantly containing the UFBs.

In the present invention, the UFB may be formed of nitrogen gas. By forming the liquid film of the liquid containing the UFBs of nitrogen gas, it is possible to maintain the surface of the substrate in the hypoxic conditions. And it is thereby possible to suppress oxidation of the surface of the substrate. Further, it is possible to suppress the liquid from adsorbing oxygen and moisture in the atmosphere during the conveyance.

### INDUSTRIAL APPLICABILITY

This invention can be applied to processing in general for processing a substrate with a processing fluid introduced in the chamber. For example, this invention can be suitably applied to single-substrate processing where substrates such as semiconductor substrates or the like are sequentially processed one by one with a supercritical fluid.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

### REFERENCE SIGNS LIST

1 substrate processing system
2 wet processing apparatus (liquid film forming part)
3 conveyance mechanism (conveyer)
4 supercritical processing apparatus
9 control part
248 processing liquid supply source
249 UFB generator (bubble)
412 processing chamber (chamber)
457 fluid supplier

1. A substrate processing method for processing a substrate with a processing fluid in a supercritical state inside a chamber, the substrate processing method comprising:
forming a liquid film by using a liquid containing ultrafine bubbles on a surface of the substrate held in a horizontal posture;
introducing the processing fluid not in the supercritical state into the chamber in which the substrate with the liquid film formed thereon is accommodated, pressurizing the processing fluid to be brought into the supercritical state, and replacing the liquid on the surface of the substrate with the processing fluid; and
decompressing the chamber, vaporizing the processing fluid in the supercritical state and discharging the processing fluid to the outside of the chamber.

2. The substrate processing method according to claim 1, wherein
the liquid contains the ultrafine bubbles each having a diameter of 1 μm or less.

3. The substrate processing method according to claim 1, wherein
the liquid contains the ultrafine bubbles each having a diameter of 0.1 μm or less.

4. The substrate processing method according to claim 1, further comprising conveying the substrate on which the liquid film is formed outside the chamber, into the chamber.

5. The substrate processing method according to claim 1, further comprising mixing the ultrafine bubbles of nitrogen gas into the liquid, wherein
the liquid in which the ultrafine bubbles are mixed is supplied onto the surface of the substrate, to thereby form the liquid film.

6. A substrate processing system for processing a substrate with a processing fluid in a supercritical state, the substrate processing system comprising:
a liquid film forming part which forms a liquid film by using a liquid containing ultrafine bubbles on a surface of the substrate held in a horizontal posture;
a chamber which accommodates therein the substrate on which the liquid film is formed; and
a fluid supplier which supplies the processing fluid not in the supercritical state into the chamber and pressurizing the processing fluid to be brought into the supercritical state.

7. The substrate processing system according to claim 6, further comprising
a conveyor which conveys the substrate on which the liquid film is formed by the liquid film forming part into the chamber.

8. The substrate processing system according to claim 6, wherein
the liquid film forming part includes a bubble generator which generating the ultrafine bubbles in the liquid.

9. The substrate processing system according to claim 8, wherein
the liquid film forming part mixes the ultrafine bubbles of nitrogen gas into the liquid.
